(19) United States
(12) Patent Application Publication
(10) Pub. No.: US 2009/0139445 A1
(43) Pub. Date: Jun. 4, 2009

(54) Device for Fabricating a Ribbon of Silicon or Other Crystalline Materials and Method of Fabrication

(75) Inventors: Roland Einhaus, Bourgoin Jallieu (FR); Francois Lissalde, Seyssins (FR); Hubert Lauvray, Paris (FR)

Correspondence Address: OLIFF & BERRIDGE, PLC, P.O. BOX 320850, ALEXANDRIA, VA, 22320-4850, US

(73) Assignees: APOLLON SOLAR, Paris (FR); CYBERSTAR, Echirolles (FR)

(21) Appl. No.: 11/992,754

(22) PCT Filed: Oct. 19, 2006
(86) PCT No.: PCT/FR2006/002349

§ 371 Date: Mar. 28, 2008

(30) Foreign Application Priority Data
Oct. 26, 2005 (FR) 0510940

(51) Int. Cl. C30B 15/06; C30B 15/00

(52) U.S. Cl. 117/27; 117/223; 117/26

(57) ABSTRACT

The device comprises a crucible (1) having a bottom (2) and side walls (3). The crucible (1) comprises at least one lateral slit (4) arranged horizontally at a bottom part of the side walls (3). The lateral slit (4) presents a width of more than 50 mm and preferably comprised between 100 mm and 500 mm. The height (H) of the slit (4) is comprised between 50 and 1000 micrometers. The crystalline material is output from the crucible via the lateral slit (4) so as to form a crystalline ribbon (R). The method comprises a step of bringing a crystallization seed into contact with the material output via the lateral slit (4) and a horizontal displacement step of the ribbon (R).

### BACKGROUND OF THE INVENTION

The invention relates to a device for fabricating a ribbon of crystalline material by controlled crystallization.

### STATE OF THE ART

Solidification of silicon from a liquid silicon bath is typically obtained by controlled crystallization, i.e. by migration of a solidification front (solid/liquid interface) from an initially solidified part, in particular a seed or a first layer crystallized by local cooling. Thus, the block of solid silicon grows progressively feeding on the liquid bath. The two methods conventionally used are the Czochralski method and the Bridgman methods or variants thereof. According to the Czochralski method, a seed, often oriented with respect to a crystalline axis of the solid silicon, is brought into contact with the melt and is slowly pulled up. The liquid silicon bath and the thermal gradient then remain immobile, whereas according to the Bridgman method, the bath is moved with respect to the thermal gradient or the thermal gradient is moved with respect to the bath.

Technological progress in the fabrication of silicon wafers such as for example wire sawing have enabled a large economical step forward to be made in the semiconductor industry and in the photovoltaic industry compared with inner diameter (ID) saws due to the undeniable gains arising from greater productivity and a reduction of the material lost when cutting is performed. Losses do however remain high and wire sawing equipment presents very high costs. Moreover, sawing requires costly additional chemical surface cleaning and restoring steps.

To overcome the problem of cutting semiconductor material, different wafer fabrication methods have been proposed such as for example pulling ribbons from a melt or growing a ribbon continuously on a substrate. However, growth of a ribbon on a substrate requires the additional step of dissociating the ribbon and substrate and presents the risk of the ribbon being contaminated by the substrate. Another technique consists in using a carbon ribbon on which silicon is crystallized, the carbon ribbon then being burnt leaving two silicon ribbons. The crystalline orientation of the wafers obtained is however more or less difficult to control and the electronic properties are therefore mediocre. In particular, for photovoltaic applications, equipment with a large minority charge carrier diffusion length is required. In the case of multicrystalline silicon for example, this is only possible if the multicrystalline material grain boundaries are perpendicular to the surface and more precisely to the P/N junctions of the photovoltaic cells.

To obtain a crystallized material quality subsequently enabling the fabrication of photovoltaic cells, it is indispensable to remove the residual impurities from the raw material (the silicon feedstock for example). One known method is segregation of the elements having a low segregation coefficient. However, for the impurities to remain in liquid phase, a thermal gradient has to be established such that the solid/liquid interface remains sufficiently stable at a given rate of progression of this interface to prevent non-controlled, equiaxed or dendritic growth of the silicon grains.

Moreover, the methods according to the prior art do not enable the production of silicon wafers from liquid silicon to be integrated in a photovoltaic cell production line.

The article “Cast Ribbon For Low Cost Solar Cells” by Hide et al. (0160-8371/88/0000-1400, 1988 IEEE) describes a method for casting a photovoltaic silicon ribbon having a thickness of 0.5 mm and a width of 100 mm. The method uses a crucible opening out into a jointed mould arranged underneath a central opening of the crucible. The jointed mould retracts so as. to form a narrow elongate guiding channel constituting an elongate die moving horizontally away from the axis of the crucible. The starting material is electronic quality silicon molten in the crucible. After it has completely melted, the silicon is injected into the jointed mould, whereby an atmospheric pressure is applied in the crucible. Solidification takes place in the narrow channel. The crystals grow upwards in the narrow channel and the solidification front is greatly inclined.

### OBJECT OF THE INVENTION

The object of the invention is to remedy the drawbacks of known devices and in particular to provide a device and method for fabrication of crystalline material ribbons by controlled crystallization enabling wafers to be obtained directly from the liquid raw material without requiring additional steps of ingot cropping, cutting the cropped ingot into bricks and slicing the bricks into wafers by wire sawing. It is a further object of the invention to integrate production of wafers directly into a photovoltaic cell line.

According to the invention, this object is achieved by the accompanying claims and more particularly by the fact that the device comprises a crucible having a bottom and side walls, the crucible comprising at least one lateral slit arranged horizontally at a bottom part of the side walls, the lateral slit presenting a width of more than 50 mm and a height comprised between 50 and 1000 micrometers.

Such a device also enables purification to be performed by segregation and silicon ribbons to thereby be obtained from less pure silicon, such as metallurgical silicon, which is therefore less expensive than very pure electronic grade silicon.

It is a further object of the invention to provide a method for fabrication of crystalline material ribbons by controlled crystallization along a crystallization axis by means of the device according to the invention, the crystallization axis being substantially perpendicular to a pulling axis of the device.

### BRIEF DESCRIPTION OF THE DRAWINGS

Other advantages and features will become more clearly apparent from the following description of particular embodiments of the invention given for non-restrictive example purposes only and represented in the accompanying drawings, in which:

FIGS. 1, 2 and 4 show three particular embodiments of the device according to the invention in cross-section.

FIGS. 3, 5 and 8 show three alternative embodiments of a crucible according to FIG. 2 in cross-section along the line A-A of FIG. 2.

FIG. 6 illustrates direct integration of the device according to the invention in a photovoltaic cell production line.

FIG. 7 illustrates the incline of the crucible and ribbon in a particular embodiment of the device according to the invention.

### DESCRIPTION OF PARTICULAR EMBODIMENTS

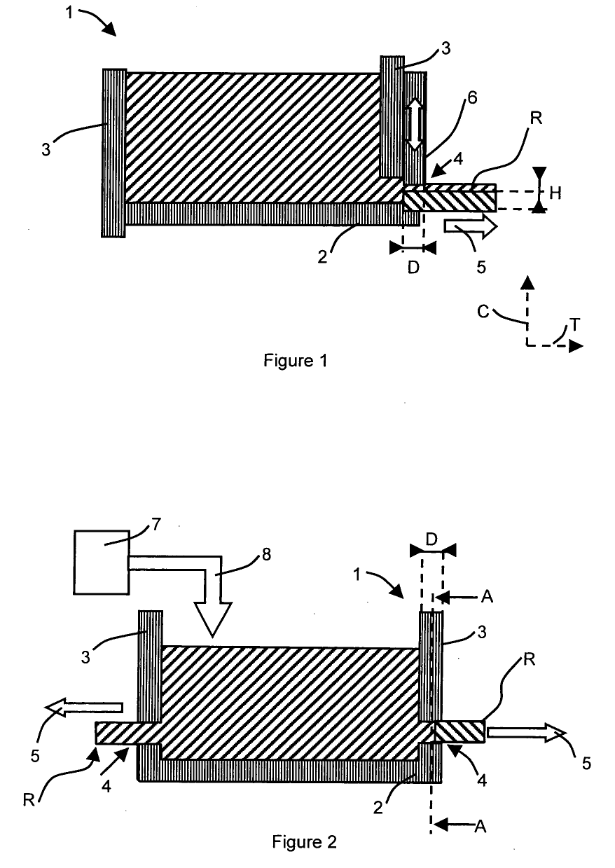

The device represented in FIG. 1 comprises a crucible 1 having a bottom 2 and side walls 3. The crucible 1 comprises a lateral slit 4 arranged horizontally at the bottom part of the right-hand side wall in FIG. 1. The lateral slit 4 presents a width L (perpendicular to FIG. 1) of more than 50 mm and preferably comprised between 100 mm and 500 mm. The height H of the slit 4 is comprised between 50 and 1000 micrometers. A ribbon R of crystalline material is thereby obtained by controlled crystallization of the material output from the lateral slit 4, which is pulled as represented by the arrow 5 in FIG. 1. The crystalline material is for example Silicon (Si), Germanium (Ge), Gallium arsenide (GaAs), Gallium phosphide (GaP), etc. . . .

The thickness of the ribbon R is determined by the height H of the slit 4 and by the pulling rate. The higher the pulling rate, the more the thickness of ribbon R decreases. The width of the ribbon R is determined by the width L of slit 4. The ribbon R can subsequently be cut into wafers, the surface of the wafers being directly formed by the surface of the ribbon R.

The solidification front, i.e. the solid/liquid interface, is located in the slit 4. As represented in FIG. 1, fabrication of the ribbon, and also of the wafers, by means of a device according to the invention enables controlled crystallization to be achieved along a crystallization axis C substantially perpendicular to a pulling axis T of the device.

According to the invention, a thermal gradient is established substantially perpendicularly to the ribbons R and/or to the pulling direction of the ribbons leaving from an opening of the crucible containing the liquid raw material. The thermal gradient is preferably located at the opening of the crucible, such as for example the slit 4. The crystallization axis C is in particular determined by the direction of the thermal gradient. The crystallization axis C is therefore substantially perpendicular to the ribbons, and therefore to the wafers. The grain boundaries of the multicrystalline material are perpendicular to the surface of the wafer and, for photovoltaic applications, perpendicular to the P/N junctions of the photovoltaic cells, thus improving the electrical properties of the material and the performance of the photovoltaic cells.

The crucible has to withstand temperatures of up to 1500° C. and to present a low reactivity with the material to be crystallized, for example with silicon. The crucible 1 is for example made of quartz, silicon nitride, graphite, quartz coated with silicon nitride or other refractory materials.

In FIG. 1, the lateral slit 4 is arranged between the bottom 2 of the crucible 1 and corresponding side wall 3, which then has to be kept away from the bottom 2. The height H of the slit 4 can if necessary be adjusted by means of an additional wall 6 adjustable in height, arranged on the external side of the crucible and enabling the height H of the lateral slit 4 to be varied, as represented in FIG. 1. The material of the additional wall 6 is preferably the same as the material of the crucible 1.

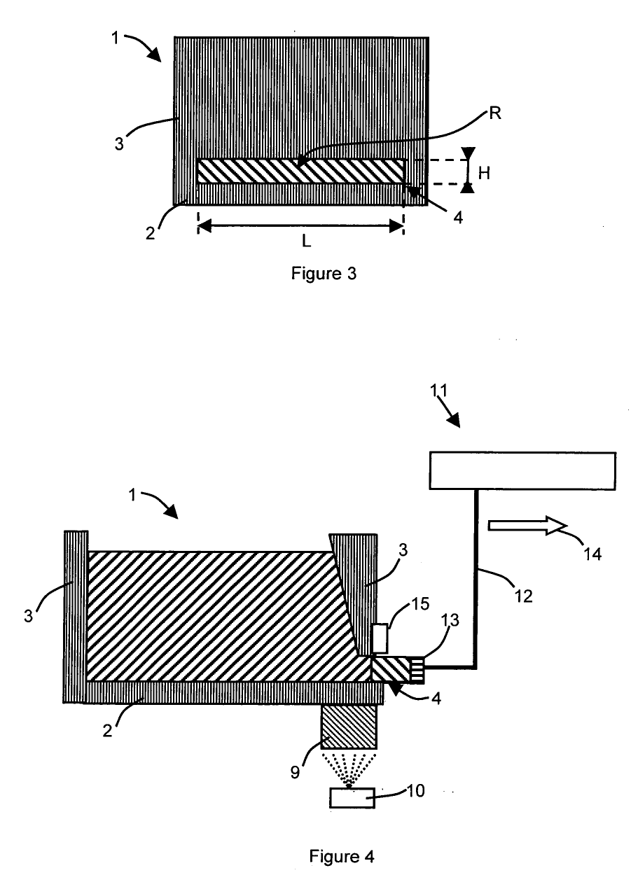

As represented in FIG. 2, the crucible can comprise several lateral slits 4 arranged for example respectively in two opposite side walls 3. Two ribbons R of crystalline material can thus be obtained simultaneously. In FIG. 2, the lateral slits 4 are machined in the bottom parts of the corresponding walls 3. FIG. 3 illustrates the lateral slit 4 extending horizontally in the direction of its width L at the bottom part of the corresponding side wall 3.

The device preferably comprises a feeding source 7 continuously supplying the crucible with the material to be crystallized, as represented by the arrow 8 in FIG. 2. The material can be fed in its solid phase or in its liquid phase. In the latter case, the device can be integrated in a raw material purification system. For example, an additional heating system and a siphonage feed can be envisaged and purification can for example be performed by plasma. In order to establish a thermal gradient within the crucible 1, the crucible is heated at the top and cooled via the bottom 2. The cooling rate has to be dimensioned to enable crystallization of the material and to absorb the latent heat corresponding to crystallization. Depending on the impurities, supercooling phenomena have to be taken into account.

To locate the liquid/solid phase separation at the level of the lateral slit 4, the crucible is preferably cooled locally at the level of the lateral slit 4, for example by means of several coiled cooling turns arranged in contact with the bottom 2 of the crucible. A coolant such as water or helium circulates in the coiled turns. In a particular embodiment represented in FIG. 4, the device comprises for example a refractory plate 9 and nebulizer 10 to deposit a coolant on the refractory plate 9. Any other local cooling device can of course be envisaged.

The location of the cooling has to be controlled so as to obtain a meniscus of the molten material formed at the level of the slit 4 that is able to crystallize when coming into contact with a crystallization nucleus. For silicon for example, the corresponding solidification temperature is comprised between 1400° C. and 1450° C., whereas the silicon melt contained in the crucible can be heated to a temperature comprised between 1420° C. and 1550° C. The silicon therefore flows through the slit 4 and crystallizes on output from the slit 4. In FIG. 4, the thickness of side wall 3 increases on moving away from the slit 4.

In FIG. 4, the device can also comprise an additional heating element 15 arranged above the slit 4 to locally heat the side wall 3 and the silicon that is solidifying at the level of the slit 4. The slit 4 is thus arranged between a hot source arranged above the slit 4 and a cold source arranged under the slit 4. This enables the thermal gradient to be established and controlled in the silicon during solidification, thereby controlling the orientation of the controlled crystallization. When a height-adjustable additional wall 6 is used, the latter can be placed in contact with additional heating element 15. The additional wall 6 can thus act as heat conductor to supply heat to the slit 4.

The thermal gradient is substantially vertical and has to be comprised between 5 and 20° C./cm in the silicon during cooling. This gradient is necessary for segregation of the impurities and for growth of grains along the substantially vertical thermal axis. The direction of growth of the grains is therefore perpendicular to the top surface of ribbon R.

The device comprises an apparatus 11 for gripping the ribbon R of crystalline material output via the lateral slit 4 of the crucible 1. The apparatus 11 for example comprises a support 12 holding crystallization a seed 13 so that the seed 13 can be placed in contact with the material output via the lateral slit 4. A monocrystalline or polycrystalline silicon seed 13 is preferably cut along a a axis of slow growth rate, for example the <112> or <110> axes, to limit growth of the grains in the pulling direction. The seed material is preferably the same as the material that is crystallizing. The seed can however be made from a different material from the crystallization material, for example quartz, nitride, polycrystalline silicon or mullite, the essential characteristic being to prevent melting and not to generate impurities. The thickness and width of the seed 13 correspond to the thickness and width of the ribbon R.

The apparatus 11 preferably also comprises a displacement motor to pull crystalline material ribbon R as represented by the arrow 14 in FIG. 4. The ribbon R can thus be pulled to a desired length and then be cut at the level of the slit 4.

FIG. 5 represents another particular embodiment of the device according to the invention comprising several lateral slits 4 arranged in one and the same side wall 3 of the crucible, each slit having for example a width of 150 mm.

Furthermore, the silicon in the crucible is heated, for example by induction, resistance, infrared radiation or a combination of these methods. The choice of methods is notably linked to the materials used.

Other steps and treatments can subsequently be added in the same production line. After leaving the crucible 1, the ribbon R can be cut for example by laser. The ribbon R is preferably cut by means of a short sharp acceleration of the pulling rate making the ribbon R break. The ribbon R thereby being separated from the material output from the slit 4, a second gripping apparatus 11 can be installed to take up the initial part of the following ribbon R. As an alternative, a lateral gripping system enables the ribbon or ribbons (or the wafers, depending on the cutting degree) to be moved one after the other.

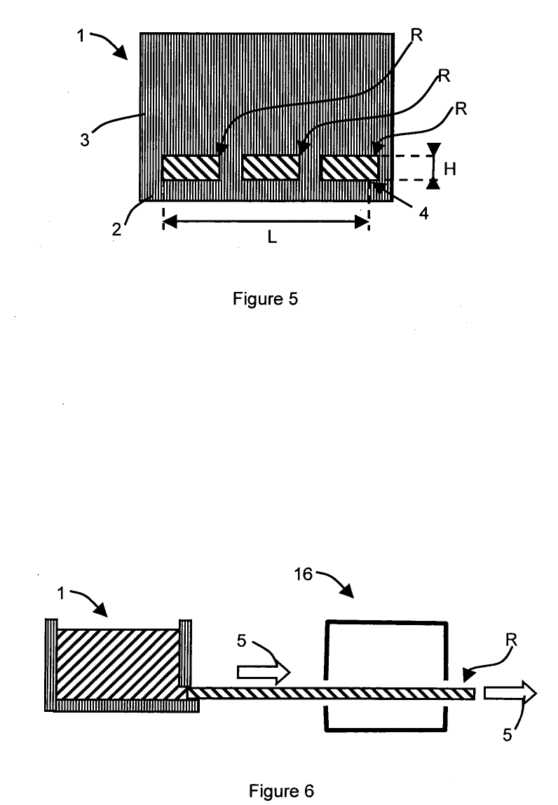

The fabrication device can be integrated directly in continuous form in a photovoltaic cell production line even before the ribbon R of material output from the slit 4 is cut into wafers. FIG. 6 thus illustrates a diffusion furnace 16 into which the ribbon R is directly introduced. A gripping and moving apparatus 11 of the ribbon R in particular enables the ribbon R to be taken to the furnace 16. As the ribbon R output from the crucible is already at high temperature, an additional preheating step is economized before introducing the ribbon R into the furnace 16.

Fully integrated production can thus be achieved from pre-purified liquid silicon to assembly of the final photovoltaic module. The device is in fact able to be integrated both up-line for receipt of the raw material and down-line for the photovoltaic cell production steps.

The method preferably comprises a step of bringing a crystallization seed 13 into contact with the material output via the lateral slit 4 and a horizontal displacement step 14 of the ribbon R.

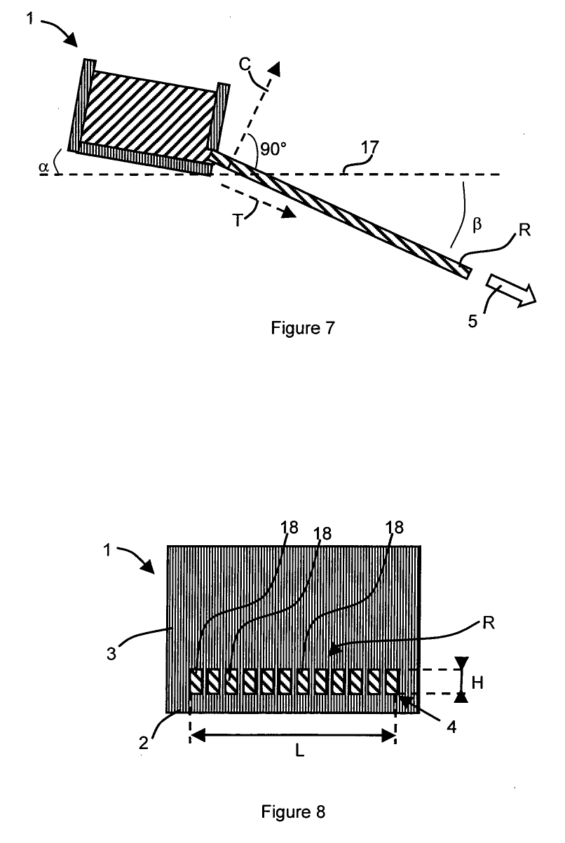

In FIG. 7, the crucible 1 is inclined at an angle α with respect to a horizontal plane 17 by means of any suitable mechanical device, for example a swivelling support. The pulling direction of the ribbon R, and therefore the ribbon R, is inclined at an angle β with respect to horizontal plane 17. This in particular facilitates crystalline growth perpendicular to the plane of the ribbon R. Indeed, the higher the pulling rate, the more the crystallization axis C inclines with respect to the pulling axis T of the device. The inclination of the crucible 1 and/or of the pulling direction enables this effect to be corrected and the crystallization C to be obtained perpendicular to the ribbon R. Angles α and β that are negative or of opposite signs can also be envisaged to control the crystallization axis C.

In a particular embodiment according to the invention represented in FIG. 8, the slit 4 is formed by a series of holes 18 spaced in such a way that threads of material passing through the holes 18 join one another on outlet from the holes to form the ribbon R. The spacing between the holes 18 can in fact be adjusted so that the individual threads output via the holes 18 are joined to one another by capillarity.

The invention is not limited to the embodiments represented. Integrating several crucibles according to the invention in a production line can in particular be envisaged. Thus a first crucible enables N-type material ribbons R to be produced and a second crucible enables P-type material ribbons R to be produced, depending on the doping of the silicon melt in the crucible.

The lateral slit 4 being arranged in the bottom part of the side walls 3 of the crucible, the depth D of the slit 4 corresponds to the thickness of the wall, which is comprised between 2.5 mm and 15 mm and preferably between 4 and 10 mm. The crucible then presents a very short outlet channel of corresponding length, i.e. a few millimeters. When the side wall 3 has a variable thickness, as represented in FIG. 4, the depth of the lateral slit 4 corresponds to the thickness of the side wall 3 at the level of the slit. In all cases, the depth D of the slit 4, or in general manner the length of the outlet channel, is comprised between 2.5 mm and 15 mm and preferably between 4 and 10 mm.

Solidification causes segregation of the impurities, i.e. a decrease of the concentration of impurities in solid phase and an increase of the concentration of impurities in liquid phase, according to the segregation coefficient of each element. On account of the slit according to the invention, the solidification front is arranged in the main volume of the crucible, or at least very close thereto. The impurities therefore disperse in the entire volume of the crucible, in particular due to the usual stirring effects. The solid phase is therefore considerably purer than the liquid phase. Consequently, the device according to the invention effectively enables a less pure initial silicon to be used than the required final silicon, and purifies same during crystallization.

On the contrary, the device described in the above-mentioned article by Hide et al. is limited to use of electronic grade silicon presenting very few impurities. The device according to Hide et al. does not in fact enable a good dispersion of the impurities throughout the entire volume of the liquid phase to be obtained, for segregation at the level of the solidification front causes the impurities to be confined in the narrow channel. The channel impurities are then necessarily included in the solid phase, in particular in the top layer of the ribbon, which presents a downgrading of the quality of the ribbon.

1. A device for fabricating a ribbon of crystalline material by controlled crystallization, comprising a crucible having a bottom and side walls, the crucible comprising at least one lateral slit arranged horizontally at a bottom part of the side walls, the lateral slit presenting a width of more than 50 mm and a height comprised between 50 and 1000 micrometers.

2. The device according to claim 1, wherein the width of lateral slit is comprised between 100 mm and 500 mm.

3. The device according to claim 1, wherein the lateral slit is arranged between the bottom of the crucible and one of the side walls.

4. The device according to claim 1, wherein the lateral slit is machined in the side wall.

5. The device according to claim 1 3, wherein the lateral slit is of variable height.

6. The device according to claim 1, comprising it comprises continuous feed means of the crucible with raw material to be crystallized.

7. The device according to claim 1, comprising it comprises cooling means to cool the bottom of the crucible locally at the level of the lateral slit.

8. The device according to claim 1, comprising heating means to heat the side wall locally at the level of the lateral slit.

9. The device according to claim 1, comprising gripping means of a ribbon of crystalline material output via the lateral slit of the crucible.

10. The device according to claim 1, comprising displacement means to pull the ribbon of crystalline material.

11. The device according to claim 1, wherein the slit is formed by a series of holes spaced in such a way that threads of material passing through the holes join one another on outlet from the holes to form the ribbon.

12. A fabrication method of a ribbon of crystalline material by controlled crystallization along a crystallization axis by means of a device according to claim 1, wherein the crystallization axis is perpendicular to a pulling axis of the device.

13. The fabrication method according to claim 12, wherein the crystalline material is output via the lateral slit, the method comprises a step of bringing a crystallization seed into contact with the material output via the lateral slit and a horizontal displacement step of the ribbon.

14. The fabrication method according to claim 12, comprising direct integration of the fabrication device in a photovoltaic cell production line.

15. The fabrication method according to claim 12, comprising inclining of the crucible and/or of the ribbon with respect to a horizontal plane.
